(19) United States
(12) Patent Application Publication
(10) Pub. No.: US 2005/0200405 A1
(43) Pub. Date: Sep. 15, 2005

(54) Audio signal amplification method and apparatus

(76) Inventors: Yoshiaki Shinohara, Yokohama (JP); Hiroyoshi Ogawa, Yokohama (JP)

Correspondence Address: DELLETT AND WALTERS, P. O. BOX 2786, PORTLAND, OR, 97208-2786, US

(21) Appl. No.: 11/049,282

(22) Filed: Feb. 1, 2005

(30) Foreign Application Priority Data
Feb. 6, 2004 (JP) 2004-030152

(51) Int. Cl. H03F 3/38

(52) U.S. Cl. 330/10

(57) ABSTRACT

In order to provide an audio signal amplification method and apparatus capable of directly connecting a load such as a speaker to a driver unit of a class-D amplifier without an LC filter, an output data from a ΔΣ converter 31 for compressing a digital audio data from a digital audio source is applied to a pulse width modulator 33 by way of a low pass filter 32 and a driver unit is controlled by a driver control circuit 35 by way of a delay device 34. A speaker 37 as a load is directly driven by P output and N output from the driver unit 36.

### FIELD OF THE INVENTION

The present invention relates to an audio signal amplification method and apparatus, more specifically to a digital audio signal amplification method and apparatus for power amplifying a digital audio signal in order to drive a load such as a speaker or the like.

### BACKGROUND ART

Audio signals are supplied from various sources including, for example, FM/AM radio receivers, digital audio sources prerecorded on CDs (compact discs), MDs (mini-discs), DVDs (digital versatile discs), etc., or analog audio sources prerecorded on audio magnetic tapes (or cassette tapes) or microphones of “karaoke” systems. It is common that users select an audio signal from such various audio signal sources depending on their choice and amplifies such selected audio signal by amplifier means in an audio system or the like before driving a load such as a speaker, a headphone or an earphone as an electro-acoustic converter.

Various amplifiers (or amplifier circuits) are proposed as amplifier means for amplifying such audio signal from various audio sources. However, because of high efficiency, i.e., lower power consumption characteristic, class-D amplifiers comprising, for example, 4 switching transistors that are connected in a bridge configuration are widely used in various audio systems and the like.

Prior art for amplifying an audio signal using such class-D amplifier are disclosed in various technical publications. A silent start class-D amplifier employing an integrator, a comparator and a switching amplifier for reducing start-up noise is disclosed in, for example, Japanese patent publication, JP-A-10-65455 (See page 4, FIG. 3 and FIG. 4).

A brief description of the conventional class-D amplifier as disclosed in the aforementioned patent publication will be made about both construction and operation by making reference to FIG. 5 and FIG. 6. The class-D amplifier 10 comprises an integrator/adder 12, a bridge driver 14, a triangle wave generator OSC, a bridge circuit 16 driven by the bridge driver 14, a speaker SP connected to the bridge circuit 16 by way of a low pass filter LPF including inductors and a capacitor LC and a feedback circuit 18 which includes a differential amplifier A2 for amplifying a voltage difference between both ends of the bridge circuit 16 before being fed back to the integrator/adder 12.

The integrator/adder 12 in the class-D amplifier 10 comprises an operational amplifier A1, an inputresistor R2, a feedback capacitor C1 connected between the output terminal and the inverting input terminal of the operational amplifier A1 and a series circuit of a resistor R3 and a switch S1 connected across the feedback capacitor C1. A reference voltage is applied to the non-inverting input terminal of the operational amplifier A1. The integrator/adder 12 operates as an integrator when the switch S1 is OFF, while operating as an adder when the switch s1 is ON. The bridge driver 14 comprises a comparator 14A having a non-inverting input terminal connected to the output terminal of the integrator 12 and an inverting input terminal to which a triangle wave generated from the triangle wave generator OSC is applied and a logic circuit 14B connected at the output side of the comparator 14A. The bridge circuit 16 comprises 4 transistors (or switching devices) Q1-Q4 such as MOS transistors or the like. The transistors Q1-Q2 are connected in series between a power supply and a reference potential source. Similarly, the transistors Q3-Q4 are connected in series between the power supply and the reference potential source. A junction point of the series connected transistors Q1-Q2 and a junction point of the series connected transistors Q3-Q4 constitute a pair output terminals of the bridge circuit 16, which are connected to both terminals of the speaker SP by way of the aforementioned low pass filter LPF and also connected to both input terminals of the differential amplifier A2 which constitutes the feedback circuit 18. And the output terminal of the differential amplifier A2 is connected to the inverting input terminal of the operational amplifier A1 in the integrator 12 by way of an output resistor.

Now, a brief operation of the class-D amplifier 10 having the construction as shown in FIG. 5 will be described by making reference to operation waveforms as shown in FIG. 6. A difference between the audio input signal inputted to the input end of the input resistor R2 in the integrator/adder 12 and the feedback signal from feedback circuit 18 is integrated by the integrator/adder 12 as an error signal as shown by A1 in FIG. 6. The integrated value is compared by the comparator 14A in the bridge driver 14 with the triangle wave A2 that is generated from the triangle wave generator OSC for obtaining a pulse width modulated modulation output A3 as shown in FIG. 6. In response to the modulation output A3, the logic circuit 14B drives to turn ON the transistors Q1 and Q4 (while turning OFF the transistors Q2 and Q3) or to turn ON the transistors Q2 and Q3 (while turning OFF the transistors Q1 and Q4) in the bridge circuit 16. As a result, a driving current flows through the speaker SP in one direction or the opposite direction by way of the low pass filter LPF. The time duration and direction of the driving current flowing through the speaker SP are controlled by the logic circuit 143 depending on whether the ON-OFF ratio of the modulation output signal (pulse) is more than or less than 50%.

Incidentally, at the power-on, the switch S1 is actuated for switching the integrator/adder 12 to the adder mode or the integrator mode in order to reject or suppress the start noise, thereby ensuring smooth start-up. The class-D amplifier 10 is able to amplify the signal with high power efficiency because the transistors Q1 and Q2 or the transistors Q3 and Q4 among the 4 transistors Q1-Q4 in the bridge circuit 16 are not driven in active (ON) states simultaneously.

Unfortunately, since the low pass filter LPF connected in front of the speaker SP is bulky as compared to active devices or IC devices such as transistors, thereby occupying a larger space, which is disadvantageous as an output amplifier for compact electronic apparatus, for example, a hearing aid or the like. Additionally, LC filters, in particular inductors accompany with resistive components, which decrease power efficiency of the amplifier.

It is therefore preferable to eliminate such LC filter in front of the speaker. For this end, disclosed is a dual comparator PWM (Pulse Width Modulation) type amplifier employing a pair of comparators at the output stage of an integrator amplifier, in which one of the comparators directly compares the output of the integrator amplifier with a triangle wave while the other comparator compares the inverted output of the integrator amplifier by way of an inverter amplifier with the triangle wave as shown in, for example, Japanese patent publication JP-A-10-126170 (See pages 4-5, FIG. 3).

In modern audio equipment, digital signals from CDs, MDs or DVDs are increasing as audio signal sources. Accordingly, audio signals from FM/AM radio receivers are digitized using an analog-to-digital converter (ADC). There is a need for signal amplification method and apparatus which amplify the digital audio signals after being processed by an integrated digital signal processor.

For example, Japanese patent publication JP-A-7-15248 discloses a digital amplifier for amplifying such digital audio signal by a class-D amplifier including 4 switching devices connected in the aforementioned bridge configuration (See pages 3-4, FIG. 4). As shown in FIG. 7 in a block diagram, such digital amplifier 20 comprises a ΔΣ converter 21 for converting an M-bit input digital audio data into an N-bit digital audio data (or data compression), a PWM modulator 22, a driver control circuit 23 and a driver unit 24. The output from the driver unit 24 drives a speaker 26 by way of a low pass filter LPF 25.

In the digital amplifier 20 as shown in FIG. 7, the digital audio data inputted to delta-sigma (ΔΣ) converter 21 has 16 bits or higher resolution. Such digital audio data is compressed by converting into an N-bit (N is normally 1-6 bits) by the ΔΣ converter 21. Moreover, such N-bit data is reduced to a 1-bit data by the PWM modulator 22. The 1-bit data from the PWM modulator 22 is inputted to the driver control circuit 23 for driving the switching devices (for example, transistors) in the driver unit 24.

As a result of the aforementioned data compression of, for example, 16 bits high resolution digital audio data into the N-bit data by the ΔΣ converter 21, there are produced not only the input signal component but also noise shaping components, PWM carrier components and peripheral signal components outside of the audible frequency band which are peculiar to ΔΣ conversion. In order to eliminate such noise components, in the conventional digital amplifier as disclosed in the aforementioned JP-A-7-15248, an LC filter (low pass filter) is essential in front of the speaker. Such LC filter is bulky and consumes a large power by the resistive components at the front stage of the speaker in which a large current flows, thereby making it difficult to achieve high efficiency.

### SUMMARY OF THE INVENTION

The present invention is made in light of the aforementioned disadvantages of the conventional digital amplifier and it is an object of the present invention to provide an audio signal amplification method and apparatus in which a load such as a speaker or the like can be driven by directly connecting such load to the output ends of the bridge circuit without connecting an LC filter.

In order to achieve the above object, the audio signal amplification method according to the present invention is an amplification method for pulse width modulating the output from the ΔΣ converter which converts to compress the input digital audio data by means of a pulse width modulator and for driving a load such as a speaker or the like by a bridge configuration driver unit which is controlled by a driver control circuit, characterized in that noise components outside of the audible frequency band in the digital audio data compressed by the ΔΣ converter are rejected before being inputted to the pulse width modulator, thereby directly driving the load by the driver unit. According to a preferred embodiment of the present invention, the noise components generated by the pulse width modulator are rejected before being inputted to the driver control circuit.

Also, the audio signal amplification apparatus according to the present invention is an amplifier including a ΔΣ converter for compressing an M-bit digital audio data into an N-bit audio output data, a pulse width modulator for pulse width modulating the output data from the ΔΣ converter, and a driver control circuit for controlling the bridge configuration driverunit which drives a load such as a speaker or the like by the 1-bit output from the pulse width modulator, characterized in the provision of a low pass filter at the output side of the ΔΣ converter for converting the N-bit output data from the ΔΣ converter into an L-bit output data. According to a preferred embodiment of the present invention, a delay device is interposed between the pulse width modulator and the driver control circuit. The delay element is inserted into only one side of the two outputs lines from the pulse width modulator. The delay device is Z⁻ⁿ, wherein n is set to any integer with the inverse of the sampling frequency being 1. The delay device comprises D-type flip-flop circuits. The low pass filter eliminates any noise outside of the audible frequency band which is generated by the ΔΣ converter. The low pass filter comprises a plurality of cascade connected delay devices and a plurality of adders for sequentially adding the output from each delay device with a preset filter coefficient.

The audio signal amplification method and apparatus according to the present invention exhibit the following significant practical advantages. That is, it is possible to directly connect a load such as a speaker or the like to the driver unit (i.e., without interposing a low pass filter such as an LC filter). Elimination of inductors occupying a large space helps to achieve miniaturization, thereby making it possible to provide a miniaturized and light-weight output stage amplifier which is essential and suitable to, for example, hearing aids. In addition, elimination of inductors essentially accompanying resistive components suppresses power consumption, which is particularly important in portable electronic apparatus having built-in batteries because the operation time of such batteries can be extended.

### BRIEF DESCRIPTION OF THE DRAWINGS

In the accompanied drawings,

FIG. 1 is a block diagram to show the basic construction of a preferred embodiment of the audio signal amplification apparatus according to the present invention;

FIG. 2 is a block diagram to show the construction of an exemplified low pass filter as shown in FIG. 1;

FIG. 3 is a block diagram of the output portion in the audio signal amplification apparatus according to the present invention;

FIG. 4 is a timing chart of an example of the present invention, wherein (A) is the P output from the driver in FIG. 4, (B) is the N output and (C) is the output signal for driving a load;

FIG. 5 is a circuit schematic of a conventional class-D amplifier for an analog audio signal;

FIG. 6 is an illustration for describing the operation of the class-D amplifier as shown in FIG. 5; and

FIG. 7 is a block diagram of a conventional class-D amplifier for a digital audio signal.

### DESCRIPTION OF PREFERRED EMBODIMENT

Now, a preferred embodiment of the audio signal amplification method and apparatus according to the present invention will be described in detail both in construction and operation by making reference to the accompanying drawings.

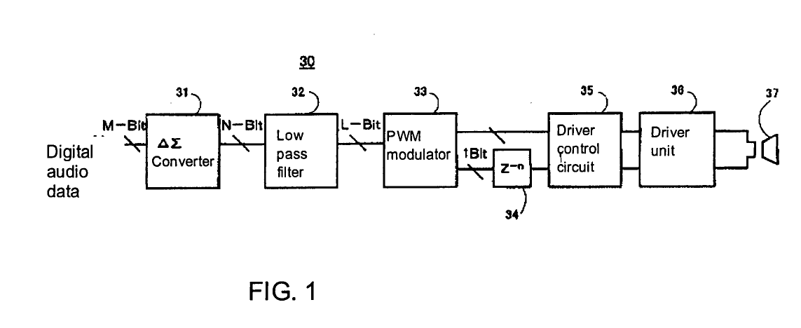

Firstly, FIG. 1 is a block diagram to show the basic construction of a preferred embodiment of the audio signal amplification apparatus according to the present invention. The audio signal amplification apparatus 30 comprises a delta-sigma (ΔΣ) converter 31, a low pass filter 32, a pulse width modulator 33, a delay device 34, a driver control circuit 35 and a driver unit 36 which are connected in a cascade manner. A speaker 37 is directly connected to the driver unit 36 as a load.

It is to be noted herein that the digital audio data to be inputted to the ΔΣ converter 31 is any digital audio data from digital audio sources such as, for example, CDs, MDs or DVDs or any digital audio data which is any analog audio signal from FM/AM radio receivers or magnetic tape players digitized by an analog-to-digital (AD) converter. Such digital audio data is an M-bit (for example, 16 bits) high resolution data. The ΔΣ converter 31 compresses the M-bit audio data by converting it into an N-bit audio data (wherein, N<M). Since the ΔΣ converter 31 may be, for example, any commercially available conventional device, no detailed description will be made herein.

The low pass filter 32 is any filter having similar characteristics to the aforementioned conventional LC filter for rejecting noise components outside of the audible frequency band which are generated by the ΔΣ converter 31. The low pass filter may be any conventional low pass filter such as, for example, an FIR filter. Also, the driver control circuit 35 is a conventional logic circuit for driving the driver unit 36 which is a conventional bridge configuration comprising, for example, 4 MOS transistors. Since the pulse width modulator 33, the driver control circuit 35 and the driver unit 36 are all conventional design, no detailed descriptions thereof will be made herein.

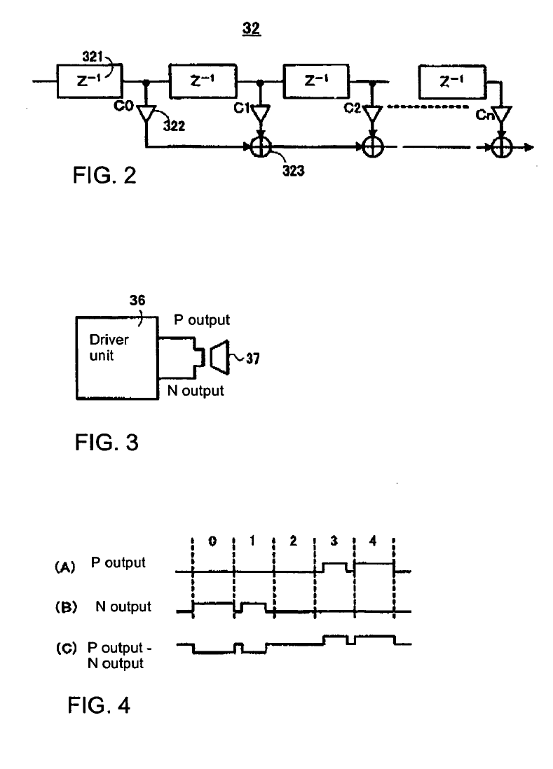

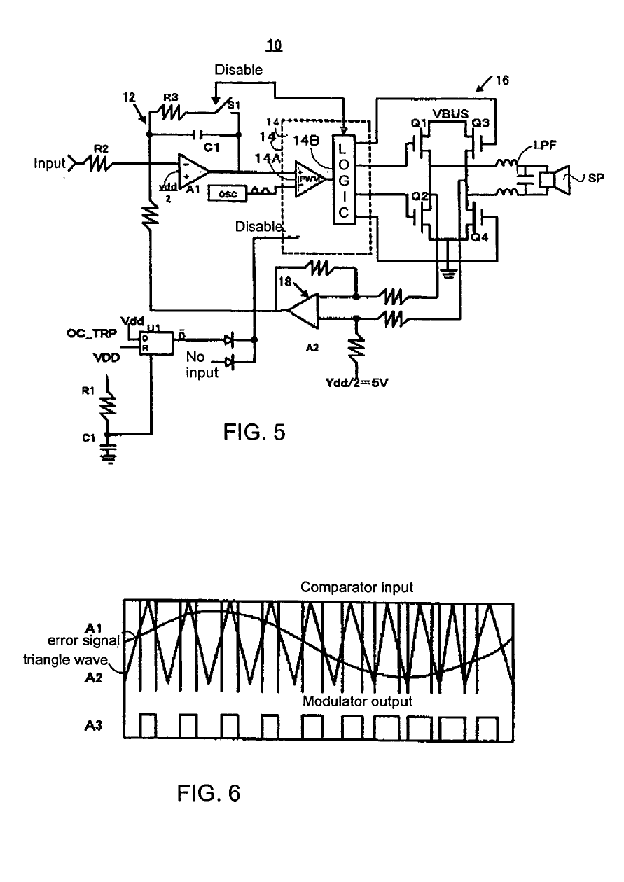

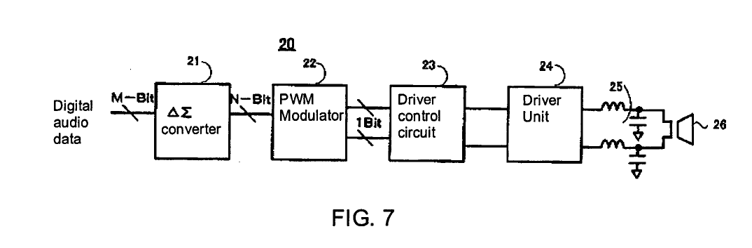

FIG. 2 is a block diagram to show an exemplified construction of the low pass filter 32. This particular example of the low pass filter 32 comprises a plurality of series connected delay devices (Z⁻¹) 321 and a plurality of adders 323 for sequentially adding the outputs from the delay devices 321 by way of respective filter coefficient circuits 322. These delay devices 321 are inverse of the sampling frequency of the ΔΣ converter 31 and comprise, for example, D-type flip-flop circuits (D-F/F). The filter coefficients C0, C1, C2, . . . , Cn of the filter coefficient circuits 322 may be 1. The filter coefficients and the number of stages may be freely chosen depending on particular applications.

Additionally, in the audio signal amplification apparatus 30 as shown in FIG. 1, the delay device (Z⁻ⁿ) 34 is interposed into one side of the two output lines from the pulse width modulator 33 for rejecting frequency components outside of the band, which are generated in the pulse width modulator 33. Wherein, n may be any integer. If Z⁻¹ is chosen, it provides the delay time equal to the inverse of the sampling frequency.

Now, description will be made about the function of interposing the delay device 34 between the pulse width modulator 33 and the driver control circuit 35. Normally, the signal to be applied to the load such as a speaker or the like is given by the following mathematical expression 1 with the plus side output of the pulse width modulator 33 being PWM_P and the minus side output of the pulse width modulator 33 being PWM_M:
Speaker signal=PWM_{—}P−PWM_{—}M (expression 1)
Wherein, if PWM_P=−PWM_M, the above expression is given by the following expression 2:
Speaker signal=PWM_{—}P+PWM_{—}P (expression 2)

Now, when the aforementioned delay device (Z⁻ⁿ) 34 is interposed in the PWM-M side as shown in FIG. 1, the speaker signal is given by the following expression 3:
Speaker signal=PWM_{—}P−PWM_{—}M*Z (expression 3)
If PWM_M in the expression 3 is replaced by PWM_P, then it is rewritten to the following expression 4
Speaker signal=PWM_{—}P+PWM_{—}P*Z⁻ⁿ=(1+Z⁻ⁿ)*PWM_{—}P (expression 4)

It is to be noted here that (1+Z⁻ⁿ) is a generic cosine filter having a frequency characteristic of a low pass filter. By adjusting n to an appropriate value, it is possible to attenuate the proper frequency components of the pulse width modulator 33.

By interposing the low pass filter 32 and the delay device (low pass filter) 34 at two circuit locations as described hereinabove, the output of the bridge circuit 35 using 4 transistors as switching devices can be connected directly to the load 37 without using the LC filter as shown in FIG. 3, thereby achieving high efficiency. Although both of the low pass filter 32 and the delay device 34 are used in the preferred embodiment of the audio signal amplification apparatus 30 as shown in FIG. 1, it is to be noted that elimination of either one of them still demonstrates a practically acceptable performance depending on applications, although may not be perfect.

Now, a detailed example of the audio signal amplification method and apparatus according to the present invention will be described by referring to FIG. 3 and FIG. 4. It is assumed that the audio input data to the ΔΣ converter 31 is 16 bits which is then compressed or converted into 1-bit data by the ΔΣ converter 31. Then, the data compressed to 1-bit is inputted to the low pass filter 32. For simplicity, all of the coefficients C0-Cn of the filter coefficient circuits 32 in FIG. 2 are set to 1.0. The filter characteristic is commonly known as a cosine filter or a comb filter. It is assumed that the filter has 4 taps. The 1-bit data outputted from the ΔΣ converter 31 is converted into multiple values as the data passes through the filter. More concretely, it takes 5 values, i.e., either 0, 1, 2, 3 or 4. The data having the five values is applied to the pulse width modulator 33 and is converted into the 1-bit data before driving the driver unit 36.

FIG. 3 shows a part of the audio signal amplification apparatus 30 according to the present invention, namely the driver unit 36 and the speaker 37 as a load that is directly connected to the P output and the N output of the driver unit 37. FIG. 4 is a timing chart to show the P output (See FIG. 4(A)), the N output (See FIG. 4(B)) from the driver unit 36 and the driving output (P output−N output) for the speaker 37 as the load in the aforementioned example.

The construction and operation of the preferred embodiment of the audio signal amplification method and apparatus according to the present invention have been described hereinabove. However, it is to be noted that the embodiment is to simply illustrate an example of the present invention and should not interpret to restrict the present invention. It is understood that a person having an ordinary skill in the art can easily make various modifications to fit particular applications without departing from the scope and spirit of the present invention. As described hereinabove, the present invention can eliminate the need for a low pass filter such as an LC filter that is connected directly to the speaker. However, in case of those applications where miniaturization and/or low power consumption is not essential, it is also possible to use a low pass filter such as an LC filter that is directly connected to the speaker for further improving noise characteristics.

1. An audio signal amplification method for pulse width modulating by a pulse width modulator the output from a ΔΣ converter for converting to compress the digital audio data to be applied thereto and for driving a load such as a speaker or the like by a bridge-form driver unit under control of a driver control circuit,
characterized in that noise components outside of the audible frequency range in the digital audio data compressed and converted by the ΔΣ converter are rejected before being applied to the pulse width modulator, thereby enabling to directly drive the load by the driver unit.

2. An audio signal amplification method in claim 1, wherein noise components introduced in the pulse width modulator are rejected before being applied to the driver control circuit.

3. An audio signal amplification apparatus including a ΔΣ converter for converting to compress an M-bit digital audio input data into an N-bit audio output data, a pulse width modulator for pulse width modulating the output data from the ΔΣ converter and a driver control circuit for controlling a bridge configuration driver unit for driving a load such as a speaker by the 1-bit output from the pulse width modulator,
characterized in the provision of a low pass filter connected to the output side of the ΔΣ converter for converting the N-bit output data from the ΔΣ converter into an L-bit output data.

4. An audio signal amplification apparatus in claim 3, wherein a delay element is interposed between the pulse width modulator and the driver control circuit.

5. An audio signal amplification apparatus in claim 4, wherein the delay element is interposed in only one side of the two output lines from the pulse width modulation circuit.

6. An audio signal amplification apparatus in claim 4, wherein the delay element is Z⁻ⁿ and n is any integer with the inverse of the sampling frequency being 1.

7. An audio signal amplification apparatus in claim 4, wherein the delay device comprises D-type flip-flop circuits.

8. An audio signal amplification apparatus in claim 3, wherein the low pass filter eliminates noise components outside of the audible frequency band introduced in the ΔΣ converter.

9. An audio signal amplification apparatus in claim 3, wherein the low pass filter comprises a plurality of series connected delay devices and a plurality of adders for sequentially adding the output from the delay devices by way of respective filter coefficients.

10. An audio signal amplification apparatus in claim 5, wherein the delay element is Z⁻ⁿ and n is any integer with the inverse of the sampling frequency being 1.

11. An audio signal amplification apparatus in claim 5, wherein the delay device comprises D-type flip-flop circuits.

12. An audio signal amplification apparatus in claim 6, wherein the delay device comprises D-type flip-flop circuits.

13. An audio signal amplification apparatus in claim 4, wherein the low pass filter eliminates noise components outside of the audible frequency band introduced in the ΔΣ converter.

14. An audio signal amplification apparatus in claim 5, wherein the low pass filter eliminates noise components outside of the audible frequency band introduced in the ΔΣ converter.

15. An audio signal amplification apparatus in claim 6, wherein the low pass filter eliminates noise components outside of the audible frequency band introduced in the ΔΣ converter.

16. An audio signal amplification apparatus in claim 7, wherein the low pass filter eliminates noise components outside of the audible frequency band introduced in the ΔΣ converter.

17. An audio signal amplification apparatus in claim 4, wherein the low pass filter comprises a plurality of series connected delay devices and a plurality of adders for sequentially adding the output from the delay devices by way of respective filter coefficients.

18. An audio signal amplification apparatus in claim 5, wherein the low pass filter comprises a plurality of series connected delay devices and a plurality of adders for sequentially adding the output from the delay devices by way of respective filter coefficients.

19. An audio signal amplification apparatus in claim 6, wherein the low pass filter comprises a plurality of series connected delay devices and a plurality of adders for sequentially adding the output from the delay devices by way of respective filter coefficients.

20. An audio signal amplification apparatus in claim 7, wherein the low pass filter comprises a plurality of series connected delay devices and a plurality of adders for sequentially adding the output from the delay devices by way of respective filter coefficients.

21. An audio signal amplification apparatus in claim 8, wherein the low pass filter comprises a plurality of series connected delay devices and a plurality of adders for sequentially adding the output from the delay devices by way of respective filter coefficients.
